(19) United States
(12) Patent Application Publication
(10) Pub. No.: US 2012/0309630 A1
(43) Pub. Date: Dec. 6, 2012

(54) PENETRATION TUBE ASSEMBLIES FOR REDUCING CRYOSTAT HEAT LOAD

(75) Inventors: Ernst Wolfgang Stautner, Niskayuna, NY (US); Kathleen Melanie Amm, Clifton Park, NY (US); Robbi Lynn McDonald, Toronto (CA); Anthony Mantone, Florence, SC (US); John Scaturro, JR., Florence, SC (US); Longzhi Jiang, Florence, SC (US); Weijun Shen, Florence, SC (US)

(73) Assignee: GENERAL ELECTRIC COMPANY, SCHENECTADY, NY (US)

(21) Appl. No.: 13/118,761

(22) Filed: May 31, 2011

(51) Int. Cl. F28F 1/00; G01R 33/035; H01L 39/02; F28F 21/06; F28F 1/40; G01R 33/34

(52) U.S. Cl. 505/162; 165/177; 165/172; 165/180; 165/133; 324/318

(57) ABSTRACT

A penetration assembly for a cryostat is presented. The penetration assembly includes a wall member having a first end and a second end and configured to alter an effective thermal length of the wall member, where a first end of the wall member is communicatively coupled to a high temperature region and the second end of the wall member is communicatively coupled to a cryogen disposed within a cryogen vessel of the cryostat.

### BACKGROUND

Embodiments of the present invention relate to cryostats, and more particularly to a design of penetration tube assemblies for use in cryostats, where the penetration tube assemblies are configured to reduce head loads to the cryostat caused by the penetration tube assemblies.

Known cryostats containing liquid cryogens, for example are used to house superconducting magnets for magnetic resonance imaging (MRI) systems or nuclear magnetic resonance (NMR) imaging systems. Typically, the cryostat includes an inner cryostat vessel and a helium vessel that surrounds a magnetic cartridge, where the magnetic cartridge includes a plurality of superconducting coils. Also, the helium vessel that surrounds the magnetic cartridge is typically filled with liquid helium for cooling the magnet. Additionally, a thermal radiation shield surrounds the helium vessel. Moreover, an outer cryostat vessel, a vacuum vessel surrounds the high temperature thermal radiation shield. In addition, the outer cryostat vessel is generally evacuated.

The cryostat generally also includes at least one penetration through the vessel walls, where the penetration is configured to facilitate various connections to the helium vessel. It may be noted that these penetrations are designed to minimize thermal conduction between the vacuum vessel and the helium vessel, while maintaining the vacuum between the vacuum vessel and the helium vessel. Moreover, it is desirable that the penetrations also compensate for differential thermal expansion and contraction of the vacuum vessel and the helium vessel. In addition, the penetration also provides a flow path for helium gas in case of a magnet quench.

Any penetration potentially increases the heat load to a cryostat from room temperature to cryogenic temperatures. The heat load mechanisms typically include thermal conduction, thermal macro and micro convection, thermal radiation, as well as thermal micro-convection. Additionally, heat load mechanisms also include thermal conduction of material, thermal link to the coldhead, thermal conduction of a helium column, thermal radiation from a side to the top of the cryostat, and thermal contact link to a cryocooler. Unlike cryostat penetrations that are open to atmosphere and are cooled by the escaping helium gas flow, closed or hermetically sealed penetrations on a cryostat are a major source of heat input for a cryostat. Additionally, penetrations are generally equipped with a safety means to ensure the quick and safe release of cryogenic gas in case of a sudden energy dump or quench of the magnet or a vacuum failure or an ice blockage.

Traditionally, early NMR and MRI systems have used boil-off from the helium bath of the cryostat and routed the boil-off gas around or through the penetration for heat exchange. The presence of a heat exchange gas within a penetration can be used for efficient cooling. In particular, if designed properly, the presence of the heat exchange gas substantially minimizes the heat load to the cryogenic system. However, NMR and MRI magnet systems, as well as other cryogenic applications, no longer permit the release of gas to the atmosphere through the penetration due to cost reasons. Additionally, due to considerable increase in the cost of helium, cryogenic systems are completely recondensing the boil-off gas.

Unfortunately, since the cooling of the gas stream is no longer available, penetrations add a considerable part to the overall heat load budget. Furthermore, the parasitic heat load of a penetration can be as high as 20 to 40% of the total heat load to the cryostat. This heat load disadvantageously leads to an inconvenient and expensive premature replacement and refurbishment of the cryocooler. The cryocooler replacement in turn increases the life-cycle cost of the MRI magnet for example.

Additionally, certain other presently available techniques for reducing the cryostat heat load caused by penetration tube assemblies entail cooling of the penetration tube assembly using a heat station linked to a coldhead cooling stage that acts as a heat sink. Unfortunately, use of these techniques reduces the cooling power of the coldhead. Moreover, other techniques address the problem of reducing the cryostat head load caused by the penetration tube assemblies by minimizing the physical dimensions of the penetration tube assemblies. However, minimizing the dimensions of the penetration tube assemblies can adversely affect the cryostat at high quench rates by leading to an increase in the internal pressure that is considerably higher than the design pressure. Moreover, bellows have been traditionally used as the penetration tube, where the convolutions of the bellows provide additional thermal length. However, even with the additional thermal length, the thermal conduction load from the bellows to the helium vessel can be significant.

It may therefore be desirable to develop a robust design of a penetration tube assembly that advantageously reduces the heat load to the cryostat caused by the penetration tube assembly, while enhancing the life span of the cryocooler.

### BRIEF DESCRIPTION

In accordance with aspects of the present technique, a penetration assembly for a cryostat is presented. The penetration assembly includes a wall member having a first end and a second end and configured to alter an effective thermal length of the wall member, where a first end of the wall member is communicatively coupled to a high temperature region and the second end of the wall member is communicatively coupled to a cryogen disposed within a cryogen vessel of the cryostat.

In accordance with aspects of the present technique, another embodiment of a penetration assembly for a cryostat is presented. The penetration assembly includes a wall member having a first end and a second end and configured to alter an effective thermal length of the wall member, where the wall member includes a plurality of tubes nested within one another, where each tube in the plurality of tubes is operatively coupled to at least one other tube in series, and where the plurality of tubes is configured to alter the effective thermal length of the wall member without use of a corrugated tube.

In accordance with yet another aspect of the present technique, a system for magnetic resonance imaging is presented. The system includes an acquisition subsystem configured to acquire image data representative, where the acquisition subsystem includes a superconducting magnet configured to receive the patient therein, a cryostat including a cryostat including a cryogen vessel in which the superconducting magnet is contained, where the cryostat includes a heat load optimized penetration tube assembly including a wall member having a first end and a second end and configured to alter an effective thermal length of the wall member, where a first end of the wall member is communicatively coupled to a high temperature region and the second end of the wall member is communicatively coupled to a cryogen disposed within a cryogen vessel of the cryostat. Moreover, the system includes a processing subsystem in operative association with the acquisition subsystem and configured to process the acquired image data.

### DRAWINGS

These and other features, aspects, and advantages of the present invention will become better understood when the following detailed description is read with reference to the accompanying drawings in which like characters represent like parts throughout the drawings, wherein:

FIG. 1 is a partial cross-sectional view of a cryostat structure;

FIG. 2 is a schematic illustration of a part of an axial cross-sectional view of one embodiment of a wall member of a penetration tube assembly for use in the cryostat of FIG. 1, in accordance with aspects of the present technique;

FIG. 3 is a schematic illustration of a part of an axial cross-sectional view of another embodiment of a wall member of a penetration tube assembly for use in the cryostat of FIG. 1, in accordance with aspects of the present technique;

FIG. 4 is a schematic illustration of a part of an axial cross-sectional view of yet another embodiment of a wall member of a penetration tube assembly for use in the cryostat of FIG. 1, in accordance with aspects of the present technique;

FIG. 5 is a schematic illustration of a part of an axial cross-sectional view of another embodiment of a wall member of a penetration tube assembly for use in the cryostat of FIG. 1, in accordance with aspects of the present technique;

FIG. 6 is a schematic illustration of a part of an axial cross-sectional view of another embodiment of a wall member of a penetration tube assembly for use in the cryostat of FIG. 1, in accordance with aspects of the present technique;

FIG. 7 is a schematic illustration of a part of an axial cross-sectional view of another embodiment of a wall member of a penetration tube assembly for use in the cryostat of FIG. 1, in accordance with aspects of the present technique; and

FIG. 8 is a schematic illustration of a part of an axial cross-sectional view of yet another embodiment of a wall member of a penetration tube assembly for use in the cryostat of FIG. 1, in accordance with aspects of the present technique.

### DETAILED DESCRIPTION

As will be described in detail hereinafter, various embodiments of a penetration tube assembly for use in a cryostat and configured to enhance the effective thermal length of the penetration tube assembly are presented. Particularly, the various embodiments of the penetration tube assemblies reduce the heat load to the cryostat caused by the penetration tube assemblies by enhancing the effective thermal length of the penetration tube assembly. By employing the penetration assemblies described hereinafter, cryostat heat loads caused by penetrations may be dramatically reduced.

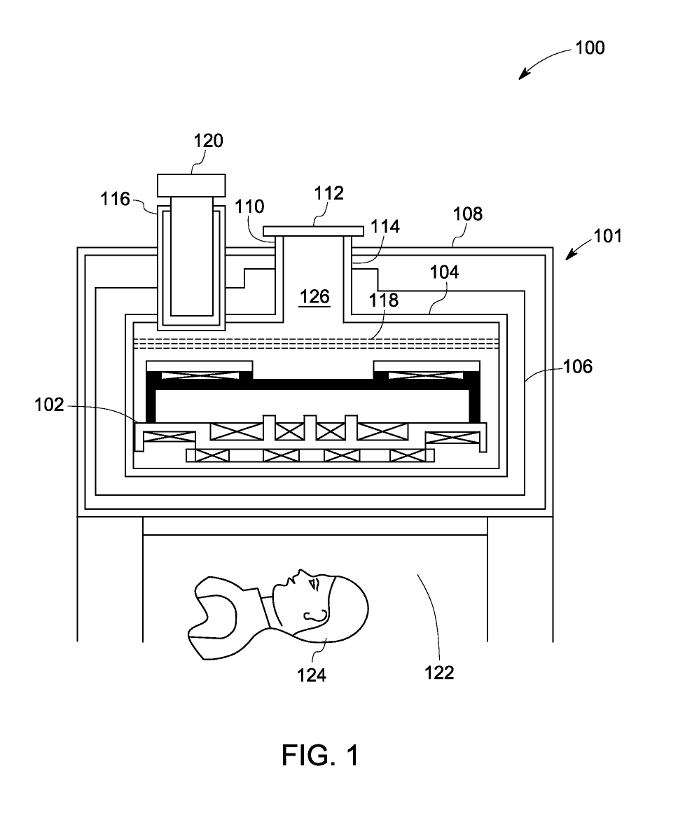

Referring to FIG. 1, a schematic diagram 100 of a sectional view of a magnetic resonance imaging (MRI) system that includes a cryostat 101 is depicted. The cryostat 101 includes a superconducting magnet 102. Moreover, the cryostat 101 includes a toroidal cryogen vessel 104, which surrounds the magnet cartridge 102 and is filled with a cryogen 118 for cooling the magnets. The cryogen vessel 104 may also be referred to as an inner wall of the cryostat 101. The cryostat 101 also includes a toroidal thermal radiation shield 106, which surrounds the cryogen vessel 104. In addition, the cryostat 101 includes a toroidal vacuum vessel or outer vacuum chamber (OVC) 108, which surrounds the thermal radiation shield 106 and is typically evacuated. The OVC may also be referred to as an outer wall of the cryostat 101. Furthermore, the cryostat 101 includes a penetration tube assembly 110, which penetrates the cryogen vessel 104 and the outer vacuum chamber 108 and the thermal radiation shield 106, thereby providing access for electrical leads. In the embodiment depicted in FIG. 1, the penetration tube assembly 110 is a closed penetration assembly having a cover plate 112, in certain embodiments. Also, reference numeral 126 is generally representative of an opening in the penetration tube assembly 110.

Also, reference numeral 114 is generally representative of a wall member of the penetration tube assembly 110. It may be noted that a first end of the wall member 114 may be operationally coupled to the OVC 108, while a second end of the wall member 114 may be operationally coupled to the cryogen vessel 104. Accordingly, the first end of the wall member 114 may be at a first temperature of about 300 degrees Kelvin (K), while the second end of the wall member 114 may be at a temperature of about 4 degrees K.

Moreover, the cryogen 118 in the cryogen vessel 104 may include helium, in certain embodiments. However, in certain other embodiments, the cryogen 118 may include liquid hydrogen, liquid neon, liquid nitrogen, or combinations thereof. It may be noted that in the present application, the various embodiments are described with reference to helium as the cryogen 118. Accordingly, the terms cryogen vessel and helium vessel may be used interchangeably.

Also, as depicted in FIG. 1, the MRI system 100 includes a sleeve 116. In certain embodiments, a cryocooler 120 may be disposed in the sleeve 116. The cryocooler 120 is employed to cool and liquefy the cryogen 118 in the cryogen vessel 104. Furthermore, reference numeral 122 is generally representative of a patient bore. A patient 124 is typically positioned within the patient bore 124 during a scanning procedure.

As previously noted, any penetration potentially leads to an increase in the heat load to a cryostat from room temperatures to cryogenic temperatures. In accordance with aspects of the present technique, various embodiments of penetration tube assemblies for use in a cryostat, such as the cryostat 101 of FIG. 1, and configured to reduce the heat load to the cryostat 101 are presented. Particularly, the penetration tube assemblies presented hereinafter are configured to reduce the heat load to the cryostat by enhancing the effective thermal length of the penetration tube assemblies.

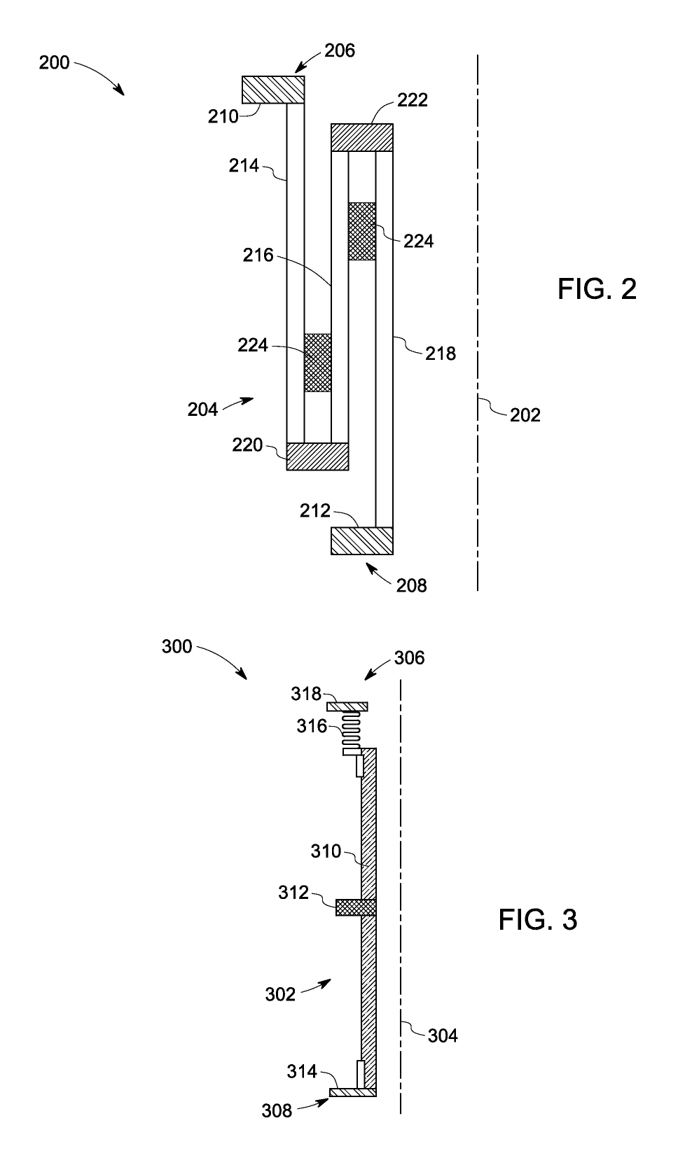

Illustrated in FIG. 2 is one embodiment of an exemplary penetration tube assembly 200 for use in a cryostat, such as the cryostat 101 of FIG. 1. In particular, FIG. 2 is a schematic illustration of a part of an axial cross-sectional view of one embodiment of a wall member 204 of a penetration tube assembly, such as the wall member 114 of FIG. 1, for use in the cryostat 101. More specifically, FIG. 2 illustrates a part of the penetration tube assembly disposed on one side of the axis of symmetry 202 of the penetration tube assembly 200. In one embodiment, the penetration tube assembly may include a cylindrical tube having a thin-walled circular cross-section. In accordance with aspects of the present technique, the exemplary penetration tube assembly 200 includes a wall member 204 that is configured to enhance an effective thermal length, thereby aiding in reducing the heat load to the cryostat caused by the penetration tube assembly. The term effective thermal length is generally used to refer to a length of a thermal conduction path of the wall member 204. In one embodiment, the penetration tube assembly 200 may be configured to enhance the length of the thermal conduction path in a range from about 50 mm to about 300 mm

In particular, in the embodiment depicted in FIG. 2, the penetration tube assembly 200 includes the wall member 204 having a first end 206 and a second end 208. In one embodiment, the first end 206 of the wall member 204 may be coupled to the OVC 108 (see FIG. 1) using a first flange 210. Furthermore, the second end 208 of the wall member 204 may be coupled to the cryogen vessel 104 (see FIG. 1) of the cryostat 101. In one embodiment, the second end 208 of the wall member 204 may be coupled to the cryogen vessel 104 using a second flange 212. In one embodiment, the first flange 210 and the second flange 212 may include stainless steel flanges. However, copper or aluminum may be used to form the first and second flanges 210, 212.

As previously noted, the first end 206 of the wall member 204 is coupled to the OVC 108. Accordingly, the first end 206 of the wall member 204 is communicatively coupled to a high temperature region. Similarly, as the second end 208 of the wall member 204 is communicatively coupled to cryogen 118 (see FIG. 1) disposed within the cryogen vessel 104 of the cryostat 101, the second end 208 of the wall member 204 is communicatively coupled to a low temperature region. Also, the high temperature region may have a temperature in a range from about 80 degrees Kelvin (K) to about 300 degrees K. Accordingly, the first end 206 of the wall member 204 that is communicatively coupled to the high temperature region may be at a temperature in a range from about 80 degrees K to about 300 degrees K.

It may be noted that the cryogen may include liquid helium, liquid hydrogen, liquid neon, liquid nitrogen, or combinations thereof. Also, as the second end 208 of the wall member 204 is in operative association with the cryogen disposed within the cryogen vessel 104 of the cryostat 101, the second end 208 may be coupled to a low temperature region. The low temperature region may be at a temperature in a range from about 4 degrees K to about 77 degrees K, in certain applications. By way of example, if the cryogen 118 is liquid hydrogen, then the low temperature region may be at a temperature in a range from about 4 degrees K to about 20 degrees K. Also, if the cryogen 118 is liquid neon, then the low temperature region may be at a temperature in a range from about 4 degrees K to about 27 degrees K. In addition, for other cryogens, the low temperature region may be at a temperature in a range from about 4 degrees K to about 77 degrees K.

According to aspects of the present technique, the wall member 204 of the penetration tube assembly 200 is configured to alter and more particularly enhance the effective thermal length of the penetration tube assembly 200, thereby reducing the heat load to the cryostat 101 caused by the penetration tube assembly. Specifically, the wall member 204 is configured to alter the effective thermal length of the penetration tube assembly 200 in a range from about 50 mm to about 300 mm To that end, in the embodiment of FIG. 2, the wall member 204 includes a plurality of tubes nested within one another. In a presently contemplated configuration, the wall member 204 includes a first tube 214, a second tube 216 and a third tube 218 nested within one another. Particularly, each tube is operatively coupled to at least one other tube in series. By way of example, a second end of the first tube 214 is operatively coupled to a first end of the second tube 216 at a first joint 220. In a similar fashion, a second end of the second tube 216 is operatively coupled to a first end of the third tube 218 at a second joint 222. This coupling of the first tube 214 to the second tube 216 and the coupling of the second tube 216 to the third tube 218 form a serial connection Accordingly, the three tubes 214, 216, 218 are nested within one another in series instead of one long tube.

With continuing reference to FIG. 2, in certain embodiments, the first tube 214 and the third tube 218 may be formed using stainless steel, while glass fiber reinforced epoxy may be used to form the second tube 216. Also, in certain other embodiments, TiAl₆V₄ or a similar Ti alloy or aluminum may be employed to form the tubes 214, 216, 218.

Moreover, in accordance with another embodiment, the first flange 210 may be coupled to the OVC 108 so as to allow the first joint 220 to be coupled to the thermal shield 106. By way of example, an intermediate link (not shown in FIG. 2) may be employed to couple the first joint 220 to the thermal shield 106. It may be noted that the thermal shield 106 is at a temperature of about 45 degrees K. The intermediate link may include a flexible braid or a copper wire that is coupled to a copper ring, which in turn is coupled to the thermal shield 106. Use of the intermediate link aids in reducing heat loads from 300 degrees K to 4 degrees K as the intermediate link is coupled to the thermal shield 106 that is at a temperature of about 45 degrees K.

Additionally, the penetration tube assembly 200 includes one or more spacer elements 224. These spacer elements 224 are configured to maintain a determined spacing between each of the three tubes 214, 216, 218 in the wall member 204. Use of the spacer elements 224 aids in ensuring that the tubes 214, 216, 218 do not flex and make contact with another tube that may lead to a thermal short. Furthermore, the spacer elements 224 may be formed using thermally non-conductive materials. In one embodiment, the spacer elements 224 may include nylon spacer elements. It may be noted that in certain embodiments, the spacer elements 224 may include a discontinuous ring so as to allow pressure balance during quench. Also, in certain embodiments, the spacer elements 224 may include holes that allow the tubers 214, 216, 218 to be at a pressure of the cryogen vessel 104. Moreover, in certain other embodiments, multi-layer insulation (MLI) (not shown in FIG. 2) may be disposed on the tubes 214, 216, 218. The MLI acts as a thermal blanket and decreases the convection of the cryogen, which in turn reduces the heat load to the cryostat 101.

Implementing the penetration assembly as described with reference to FIG. 2 provides a compact design of the penetration assembly. Particularly, the penetration assembly of FIG. 2 provides an effective thermal conduction path of enhanced length, while maintaining a shorter total overall path length of the penetration tube assembly from 300 degrees K to 4 degrees K. Consequently, there is an increase in the available cross-sectional area of the penetration tube assembly 200 during the quench of the magnet without additional heat load penalty. This increase in the available cross-sectional area of the penetration tube assembly 200 in turn facilitates enhanced dissipation of heat, thereby reducing the head load to the cryostat 101 caused by the penetration tube assembly 200. Also, the wall member 204 of FIG. 2 advantageously enhances the effective thermal length of the penetration tube assembly 200 without the use of any bellows and/or corrugated tubes that have been traditionally used to enhance the effective thermal length.

Moreover, these nested tubes 214, 216, 218 may be optimized for shrinkage and/or expansion of the penetration tube during the quench of the magnet. By way of example, the first tube 214 may shrink in an upward direction, the second tube 216 may shrink in a downward direction, while the third tube 218 may also shrink in an upward direction. Nesting the tubes 214, 216, 218 as described hereinabove allows compensation of the total shrinkage by about 33%. In addition, the nested tubes 214, 216, 218 may also be optimized for transport of the cryostat 101. By way of example, the design of the wall member 204 and more particularly the design of the tubes 214, 216, 218 may be optimized using appropriate material combinations to minimize shrinkage of the tubes. In one example, a material called “Dyneema” that expands when cooled down to 4 degrees K may be employed and thus can further minimize the total shrinkage of the overall penetration tube assembly.

Also, in one embodiment, the tubes 214, 216, 218 may include stainless steel tubes of varying diameters. However, other materials, such as, but not limited to, alloys of Titanium, Inconel, non-metallic epoxies and carbon based tubes, may be used to form the tubes. It may be noted that in certain embodiments, the first joint 220 and the second joint 222 may be ring-shaped. Furthermore, in one example, the ring-shaped second joint 222 may be formed from aluminum if the cryogen vessel 104 is an aluminum vessel. Also, the first joint 220 may be friction welded to the stainless steel tubes. Additionally, the first and second joints 220, 222, if used as a location for a thermal link to the thermal shield 106, may be formed from friction-welded copper. However, if the tubes 214, 216, 218 include non-metallic tubes, the joint rings may be glued on metallic rings.

Referring now to FIG. 3, another embodiment 300 of an exemplary wall member 302 of a penetration tube assembly configured for use in a cryostat is depicted. Particularly, FIG. 3 is a schematic illustration of a part of an axial cross-sectional view of another embodiment of a wall member 302 of a penetration tube assembly for use in the cryostat 101 (see FIG. 1). Also, reference numeral 304 is generally representative of the axis of symmetry of the penetration tube. The wall member 302 has a first fixed end 306 and a second fixed end 308. Furthermore, a non-conducting composite material may be employed to form the wall member 302. In the embodiment of FIG. 3, the wall member 302 includes a glass fiber reinforced plastic (GRP) tube. Alternatively, the wall member 302 may include a carbon fiber composite (CFC) tube, in certain embodiments.

Moreover, a thin stainless tape 310 is wrapped on the outer GRP tube surface to form the wall member 302. Wrapping the stainless steel tape 310 on the outer tube surface aids in minimizing helium gas permeation through the GRP or CFC type penetration tube. The stainless steel tape 310 thus acts as an efficient permeation barrier. Additionally, the stainless steel tape 310 is further employed to stiffen the GRP tube. Moreover, the stainless steel tape 310 also aids in the prevention of expansion of the GRP tube due to internal pressure build up during quench. The stainless steel tape 310 also enhances the pressure bearing capability of thin-walled tubes by applying a braided layer mesh around the tube. Also, in one embodiment, the stainless steel tape 310 may have a thickness in a range from about 1 mil to about 5 mil.

Furthermore, in certain embodiments, the wall member 302 may also include a heat station ring 312. The heat station ring 312 may be formed using copper, in one embodiment. Also, the heat station ring 312 provides a thermal link to a cryocooler, such as the cryocooler 120 of FIG. 1. In particular, the heat station ring 312 is configured and positioned so as to aid in the prevention of buckling of the GRP tube due to internal tube pressure build up during a quench of the magnet. The heat station ring 312 may also be operationally coupled to the thermal shield 106 (see FIG. 1) of the cryostat 101 of FIG. 1. One or more flexible braids (not shown in FIG. 3) may be employed to operationally couple the heat station ring 312 to the thermal shield 106 and enable transfer of heat out of the penetration tube assembly. In certain embodiments, the flexible braids may include copper braids. Also, a copper ring (not shown in FIG. 3) may be used to facilitate coupling of the wall member 302 to the thermal shield 106. In one embodiment, the copper ring may be embedded in the wall member 302. Additionally, a cryocooler, such as the cryocooler 120 of FIG. 1, may be coupled to the thermal shield 106, where the cryocooler is used to maintain the thermal shield temperature at about 45 degrees K.

The second end 308 of the wall member 302 is coupled to the cryogen vessel 104 (see FIG. 1) via a first flange 314. Additionally, in the presently contemplated configuration of FIG. 3, the first end 306 of the wall member 302 may be operatively coupled to a corrugated tube member 316. The corrugated tube member 316 is in turn coupled to the cryogen vessel 104 of the cryostat 101 via a second flange 318. In certain embodiments, the first flange 314 and the second flange 318 may be formed using stainless steel, aluminum or copper.

As will be appreciated, there exists a temperature gradient from about 300 degrees K to about 4 degrees K across the length of the penetration tube assembly during normal operation of the cryostat. However, during a quench, this temperature gradient fades and consequently there is a substantially uniform temperature over the whole length of the penetration tube assembly, thereby reducing the tube temperature to a range from about 5 degrees K to about 10 degrees K. This lack of a temperature gradient disadvantageously increases the stress and strain in the penetration tube assembly and may result in the shrinking of the GRP tube of the wall member 302 during a quench of the magnet. In the embodiment of FIG. 3, the corrugated tube member 316 is configured to aid in enhancing the effective thermal length of the wall member 302. In particular, the corrugated tube member 316 is employed to compensate for the shrinkage of the GRP tube during the quench, which in turn substantially minimizes axial stress concentrations within the penetration tube assembly. The corrugated tube member 316 also aids in compensating for the thermal expansion of the penetration tube assembly and during transport Implementing the penetration tube assembly as depicted in FIG. 3 substantially minimizes the heat load to the cryostat 101 caused by the penetration tube assembly.

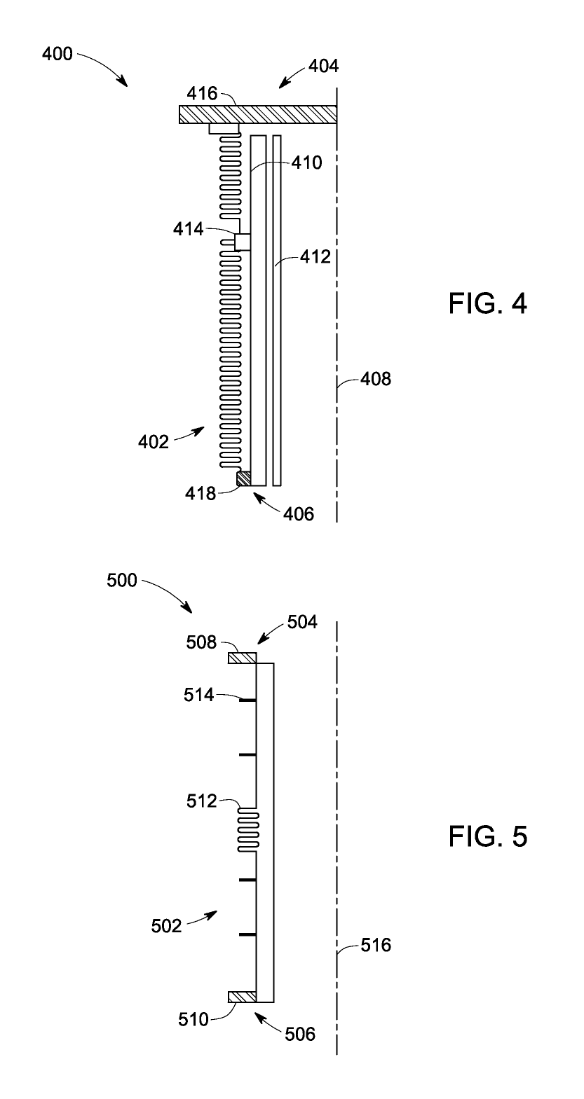

FIG. 4 depicts yet another embodiment 400 of a wall member 402 of a penetration tube assembly for use in a cryostat, such as the cryostat of FIG. 1. Particularly, FIG. 4 is a schematic illustration of a part of an axial cross-sectional view of another embodiment of a wall member 402 of a penetration tube assembly for use in the cryostat. Also, reference numeral 408 is generally representative of the axis of symmetry of the penetration tube. The wall member 402 has a first end 404 and a second end 406 and configured to enhance the effective thermal length of the wall member 402. In the illustrated embodiment of FIG. 4, the wall member 402 includes a corrugated tube. This corrugated tube aids in enhancing the effective thermal length of the wall member 402.

Additionally, the penetration tube assembly 400 includes a thin-walled tube 410 that is disposed adjacent to the wall member 402. In certain embodiments, the thin-walled tube 410 may include an epoxy tube. Alternatively, in certain other embodiments, the thin-walled tube 410 may include a stainless steel tube. Also, the thin-walled tube 410 may be a smooth tube, in certain embodiments, thereby aiding in enhancing quench gas flow. In certain embodiments the thin-walled tube 410 may also be a corrugated tube.

Moreover, in accordance with aspects of the present technique, a foil 412 may be disposed in an annular space between the thin-walled epoxy tube 410 and the wall member 402. It may be noted that the foil 412 may include a Mylar foil, a nylon foil, a polyethylene type foil, and the like. The foil 412 may be configured to minimize heat exchange by convection and conduction between the tubes 402 and 410. By way of example, the foil 412 may be configured to minimize heat exchange by gaseous micro-convection of type Bénard. This type of convection typically appears between two parallel horizontal surfaces that are maintained at different temperatures. Microconvection within the corrugations potentially “short out” the thermal path length, thereby substantially reducing the thermal path length and hence increasing the heat load from room temperature to about 4 degrees K.

Furthermore, in one embodiment, one or more spacer elements 414 may be disposed between the corrugated tube wall member 402 and the thin-walled epoxy tube 410. These spacer elements 414 aid in maintaining a uniform spacing between the corrugated wall member 402 and the thin-walled stainless steel or epoxy tube 410. The spacer elements 414 may include nylon spacer elements with through holes, in certain embodiments. Moreover, the spacer elements 414 also serve as a structural support for the foil 412. Also, the position of the spacer elements 414 allows a heat link to the thermal shield 106 to be formed. Particularly, the heat link may be a thermal sinking station. In one embodiment, the heat link may be a ring-shaped flange that couples the spacer elements 414 to the thermal shield 106. Alternatively, the heat link may include a flexible copper braid. Reference numeral 416 is generally representative of a flange that aids in coupling the first end 404 of the corrugated tube wall member 402 to the OVC 108 (see FIG. 1).

Also, the second end 406 of the corrugated wall member 402 is operatively coupled to the cryogen vessel 104 (see FIG. 1) using a rounded entry flange 418. In certain embodiments, the rounded entry flange 418 is welded to an opening in the cryogen vessel 104. The rounded entry flange 418 is configured to decrease entrance flow resistance, thereby enhancing quench gas flow and reducing pressure build up in the helium vessel. Implementing the penetration tube assembly as depicted in FIG. 4 structurally stabilizes the tubes 402, 410 since the corrugated tube wall member 402 is operatively coupled to the thermal shield 106 via the spacer element 414, in one embodiment.

Turning now to FIG. 5, another embodiment 500 of a wall member 502 of a penetration tube assembly for use in a cryostat, such as the cryostat of FIG. 1. In particular, FIG. 5 is a schematic illustration of a part of an axial cross-sectional view of another embodiment of a wall member 502 of a penetration tube assembly for use in the cryostat. In one embodiment, the wall member 502 may be representative of the thin-walled tube 410 of FIG. 4. Also, reference numeral 516 is generally representative of the axis of symmetry of the penetration tube. In the embodiment depicted in FIG. 5, the thin-walled epoxy tube may generally be referenced by reference numeral 502. Also, the thin-walled epoxy tube 502 has a first end 504 and a second end 506. The first end 504 of the thin-walled epoxy tube 502 is coupled to the OVC 108 (see FIG. 1) via a first flange 508, while the second end 506 of the thin-walled epoxy tube 502 is coupled to the cryogen vessel 104 (see FIG. 1) of the cryostat 101 via a second flange 510. In certain embodiments, the first and second flanges 508, 510 may be formed using stainless steel, copper or aluminum.

Furthermore, in accordance with aspects of the present technique, the thin-walled epoxy tube 502 includes a corrugated tube member 512. The corrugated tube member 512 aids in enhancing the effective thermal length of the wall member 502 during a quench of the magnet. Particularly, the corrugated tube member 512 is configured to compensate for the sudden shrinkage of the wall member 502 during a quench. Also, in one embodiment, the thin-walled tube 502 may be formed using TiAl₆V₄. Use of TiAl₆V₄ to form the thin-walled tube 502 substantially enhances the pressure bearing capability of the thin-walled tube 502.

Additionally, in accordance with aspects of the present technique, the thin-walled tube 502 includes one or more stiffeners or stiffening elements 514 operatively coupled to the thin-walled tube 502. These stiffening elements 514 may be formed from stainless steel, in certain embodiments. However, in certain other embodiments, the stiffening elements 514 may be formed using TiAl₆V₄. Furthermore, the stiffening elements 514 are configured to enhance the pressure bearing capability of the thin-walled tube 502. Particularly, the stiffening elements 514 work with pressure that is internal to the thin-walled tube 502 and the pressure that is external to the thin-walled tube 502 in a substantially similar fashion. Also, use of the stiffening elements 514 does not significantly affect the heat load to the cryostat 101 Implementing the thin-walled tube 502 that includes the stiffening elements 514 allows use of thin-walled tubes of reduced thickness.

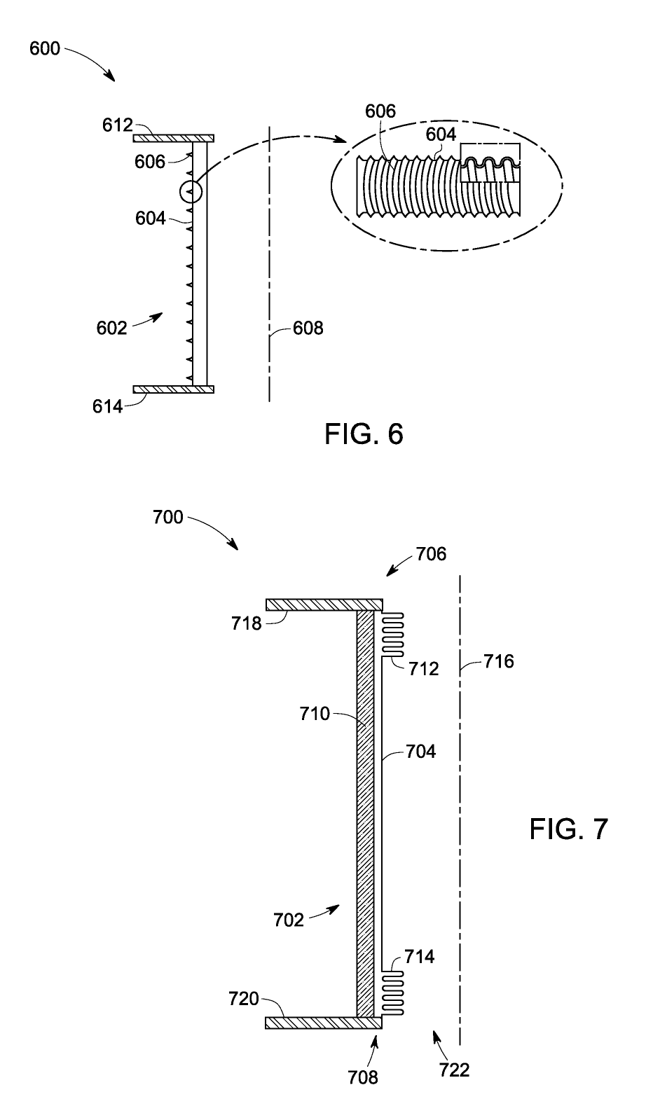

Referring now to FIG. 6, another embodiment 600 of a wall member 602 configured for use in penetration tube assembly of the cryostat 101 if FIG. 1 is depicted. Specifically, FIG. 6 is a schematic illustration of a part of an axial cross-sectional view of another embodiment of a wall member 602 of a penetration tube assembly for use in the cryostat. Also, reference numeral 608 is generally representative of the axis of symmetry of the penetration tube. In the embodiment illustrated in FIG. 6, the wall member 602 includes a flexible tube 604. The flexible tube 604 may be formed using Polyethylenvinylchloride PVC, Nylon, Polyamide, Polystryroles, polyethylenes, carbon or epoxy composite structures, or combinations thereof. In addition, the wall member 602 includes a flexible spiral tube member 606 disposed on or around the flexible tube 604. The flexible spiral tube member 606 may include a stainless steel wire, in certain embodiments. The flexible tube 604 is configured to expand under pressure and is supported by the spiral tube member 606 wrapped around the composite flexible tube 604. The design of the embodiment of FIG. 6 allows use of a relatively thin-walled flexible tube 604 that is reinforced by the spiral tubing 606 disposed around the flexible tube 604 during a quench. Moreover, the wall member 602 of FIG. 6 allows the wall member 602 to quickly reduce the opening diameter after the quench due to the spiral flexible tubing 606 that is disposed around the flexible tube member 604.

Moreover, a first end of the wall member 602 is coupled to the OVC 108 (see FIG. 1) via a first flange 612, while a second end of the wall member 602 is coupled to the cryogen vessel 104 (see FIG. 1) via a second flange 614. The first and second flanges 612, 614 may be formed using stainless steel, copper or aluminum.

FIG. 7 depicts yet another embodiment 700 of a wall member 702 configured for use in a penetration tube assembly of a cryostat. In particular, FIG. 7 is a schematic illustration of a part of an axial cross-sectional view of another embodiment of a wall member 702 of a penetration tube assembly for use in the cryostat. Also, reference numeral 716 is generally representative of the axis of symmetry of the penetration tube. In this embodiment, the wall member 702 includes a thin-walled tube 704 having a first end 706 and a second end 708. The first end 704 of the thin-walled tube 702 is coupled to the OVC 108 via a first flange 718 and the second end 706 of the thin-walled tube 702 is coupled to the cryogen vessel 104 of the cryostat 101 via a second flange 720. In certain embodiments, the first and second flanges 718, 720 may be formed using stainless steel.

The thin-walled tube 704 may be formed using a material having low-thermal conductivity. By way of example, the low-thermal conductivity material may include Invar, Inconel, Titanium alloy, or composite type materials, such as, but not limited to, glass fiber reinforced epoxy or carbon fiber composites structures.

Additionally, in accordance with aspects of the present technique, the wall member 702 includes a braided sleeve 710 that is disposed on an outer wall surface of the thin-walled tube 704. The braided sleeve 710 is configured to reinforce the thin-walled tube 704. Also, the braided sleeve 710 may be formed using a material having low-thermal conductivity. By way of example, polyethylene, nylon, polyamide, GRP, CFC, and the like may be employed to form the braided sleeve 710. As the pressure builds up in the cryostat 101 during a quench, the thin-walled tube 704 tends to buckle. Use of the braided sleeve 710 on the thin-walled tube 704 aids in reducing internal pressure on the thin-walled tube 704 during a quench.

Furthermore, a first corrugated member 712 may be coupled to the first end 706 of the thin-walled tube 704, while a second corrugated member 714 may be coupled to the second end 708 of the thin-walled tube 704. These corrugated members 712, 714 also aid in enhancing the effective thermal length of the wall member 702 and simultaneously minimizing axial stress buildup within the tube during a quench. Also, during a quench, the cryogen 118 (see FIG. 1) flows from the cryogen vessel 104 through an opening 722 in the thin-walled tube 704 to the OVC 108. The depicted embodiment of FIG. 7 is devoid of a heat station ring. However, in certain embodiments, use of a heat station ring is envisaged Implementing the penetration tube assembly as depicted in FIG. 7 enhances the effective thermal length of the wall member 704, thereby reducing the heat load to the cryostat 101 caused by the penetration tube assembly. Also, use of the braided sleeve 710 enhances the pressure bearing capability of the thin-walled tube 704.

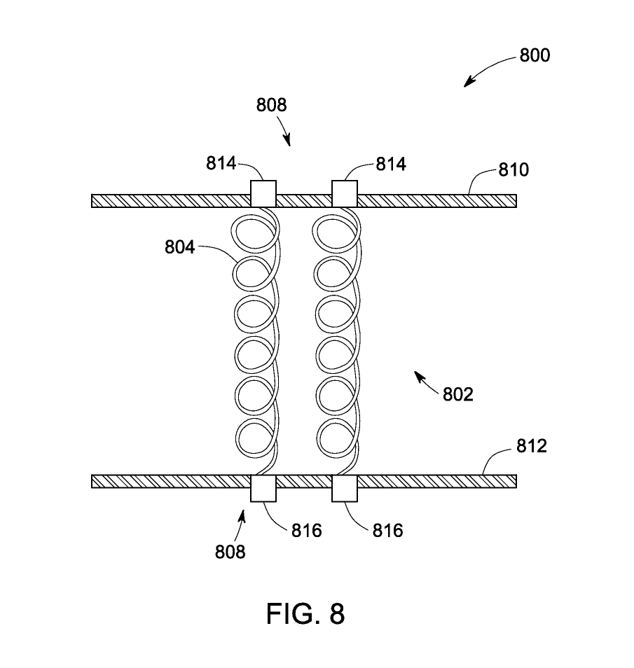

Turning now to FIG. 8, another embodiment 800 of a wall member 802 configured for use in a penetration tube assembly of the cryostat 101 of FIG. 1 is illustrated. In a presently contemplated configuration, the wall member 802 includes a pair of corrugated flexible tubing 804 that are coiled together. In particular, the corrugated flexible tubing 804 is selected such that the cross-sectional area of all the tubes enables release of quench gas. Furthermore, the flexible tubing 804 is fashioned in a spiral form to enhance the overall effective thermal length of the wall member 802. In addition, the flexible coiled tubing 804 is configured to expand and contract to aid in the release of quenched gas. It may be noted that in certain embodiments, the wall member 802 may include non-cylindrical tubes.

In addition, the relatively wide opening of the penetration tube assembly 110 of FIG. 1 is segmented into one or more relatively smaller openings, thereby reducing the heat load to the cryostat 101 caused by the penetration tube assembly. Particularly, in the embodiment depicted in FIG. 8, the penetration tube assembly 800 has a closed first end and a closed second end. Additionally, the wall member 802 and in particular the corrugated flexible tubing 804 has a first end 806 and a second end 808. The first end 806 of the wall member 802 is coupled to the OVC 108 (see FIG. 1) via a first flange 810, while the second end 808 of the wall member 802 is coupled to the cryogen vessel 104 (see FIG. 1) via a second flange 812. As previously noted, the first and second flanges 810, 812 may be formed using stainless steel, copper or aluminum.

In accordance with aspects of the present technique, the first end 806 of the corrugated flexible tubing 804 opens to the OVC 108 via openings 814, while the second end 808 of the corrugated flexible tubing 804 opens to the cryogen vessel 104 via openings 816. Particularly, the closed second end 808 of the penetration tube assembly is segmented into one or more relatively smaller openings 816. More specifically, the closed second end 808 has openings 816 that allow the cryogen (see FIG. 1) to travel from the cryogen vessel 104 (see FIG. 1) to the OVC 108 (see FIG. 1) through the corrugated flexible tubing 804. By way of example, during a quench, the cryogen 118, such as helium, from the cryogen vessel 104 may enter the flexible tubes 804 through the openings 816 and flow through the tubes 804 towards the OVC 108 through the openings 814. Implementing the penetration tube assembly as depicted in FIG. 8 presents a very low heat burden on the cryostat 101 due to the coiled geometry of the wall member 802.

The various embodiments of the exemplary wall members of the penetration tube assembly configured for use in a cryostat described hereinabove dramatically reduce the heat load to the cryostat caused by the penetration tube assembly by enhancing the effective thermal length of the wall member of the penetration tube assembly. The lower thermal burden on the cryostat advantageously results in increasing the ride-through time, extending coldhead service time, and cost saving. By way of example, the simplified design of the penetration tube assemblies reduces the cost of the overall system. Additionally, use of the exemplary penetration tube assemblies circumvents the need for a thermal link to the coldhead, in certain instances. Furthermore, as previously noted, the penetration accounts for at least 30 to 40% of the heat load of a system. The low heat load to the cryostat resulting from the use of the exemplary penetration tube assemblies described hereinabove potentially aids in reducing the total helium inventory required in a cryostat. The various embodiments of the penetration tube assemblies described hereinabove therefore present a heat load optimized penetration, which is a key factor for successful cryostat design.

Additionally, in certain embodiments, the effective thermal length of the wall member may be enhanced without the use of bellows. Also, the exemplary penetration tube assemblies enhance the ease of gas flow during the quench of the magnet by enabling a free passageway.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A penetration tube assembly for a cryostat, the penetration tube assembly comprising:
a wall member having a first end and a second end and configured to alter an effective thermal length of the wall member, wherein a first end of the wall member is communicatively coupled to a high temperature region and the second end of the wall member is communicatively coupled to a cryogen disposed within a cryogen vessel of the cryostat.

2. The penetration tube assembly of claim 1, wherein the high temperature region has a temperature in a range from about 80 degrees K to about 300 degrees K.

3. The penetration tube assembly of claim 1, wherein the cryogen comprises liquid helium, liquid hydrogen, liquid neon, liquid nitrogen, or combinations thereof.

4. The penetration tube assembly of claim 1, wherein the wall member is configured to alter the effective thermal length of the wall member in a range from about 50 mm to about 300 mm.

5. The penetration tube assembly of claim 1, wherein the wall member comprises a plurality of tubes nested within one another, and wherein each tube in the plurality of tubes is operatively coupled to at least one other tube in series.

6. The penetration tube assembly of claim 5, wherein the plurality of tubes is configured to alter the effective thermal length of the wall member without use of a corrugated tube.

7. The penetration tube assembly of claim 5, wherein the plurality of tubes comprises stainless steel tubes, glass fiber reinforced epoxy tubes, TiAl₆V₄ tubes, aluminum tubes, or combinations thereof.

8. The penetration tube assembly of claim 5, further comprising one or more spacer elements configured to maintain a determined spacing between each tube in the plurality of tubes.

9. The penetration tube assembly of claim 1, wherein the wall member comprises:
a glass fiber reinforced plastic tube; and
a stainless steel tape disposed on an outer wall surface of the glass fiber reinforced plastic tube.

10. The penetration tube assembly of claim 9, further comprising a heat link coupled to the glass reinforced plastic tube and configured to decrease the heat load to the cryostat.

11. The penetration tube assembly of claim 9, further comprising a corrugated section operatively coupled to a first end of the glass reinforced plastic tube and configured to alter the effective thermal length of the glass reinforced plastic tube.

12. The penetration tube assembly of claim 1, wherein the wall member comprises a corrugated tube.

13. The penetration tube assembly of claim 12, further comprising:
a thin-walled tube disposed adjacent to the wall member; and
a foil disposed in an annular space between the thin-walled tube and the wall member and configured to minimize heat exchange between the cryogen and the wall member.

14. The penetration tube assembly of claim 13, further comprising one or more spacer elements disposed between the wall member and the thin-walled tube and configured to maintain a determined spacing between the wall member and the thin-walled tube.

15. The penetration tube assembly of claim 1, further comprising one or more stiffening elements disposed along the wall member and configured to increase the pressure bearing capability of the wall member and to reinforce the wall member to minimize buckling of the wall member.

16. The penetration tube assembly of claim 15, wherein the one or more stiffening elements comprises stainless steel stiffening elements, TiAl₆V₄ stiffening elements, or a combination thereof.

17. The penetration tube assembly of claim 1, wherein the wall member comprises:
a thin-walled tube: and
a spiral flexible tubing disposed thereon.

18. The penetration tube assembly of claim 1, wherein the wall member comprises a composite tube, wherein the composite tube comprises:
a thin-walled tube; and
a braided hose disposed on an outer surface of the thin-walled tube.

19. The penetration tube assembly of claim 18, further comprising a corrugated section operatively coupled to the first end, the second end, or both the first end and the second end of the wall member.

20. The penetration tube assembly of claim 1, wherein the wall member comprises a plurality of flexible tubes patterned in a spiral form.

21. The penetration tube assembly of claim 20, wherein each of the plurality of flexible tubes comprises a first end and a second end, wherein the first end opens into an outer vacuum chamber of the cryostat and the second end opens into a cryogen vessel of the cryostat, and wherein the second end allows a cryogen to flow from the cryogen vessel through the flexible tube to the outer vacuum chamber through the first end.

22. A penetration tube assembly for a cryostat, the penetration tube assembly comprising:
a wall member having a first end and a second end and configured to alter an effective thermal length of the wall member, wherein the wall member comprises a plurality of tubes nested within one another, wherein each tube in the plurality of tubes is operatively coupled to at least one other tube in series, and wherein the plurality of tubes is configured to alter the effective thermal length of the wall member without use of a corrugated tube.

23. A system for magnetic resonance imaging, comprising:
an acquisition subsystem configured to acquire image data representative of a patient, wherein the acquisition subsystem comprises:
a superconducting magnet configured to receive the patient therein;
a cryostat comprising a cryogen vessel in which the superconducting magnet is contained, wherein the cryostat comprises a heat load optimized penetration tube assembly comprising:
a wall member having a first end and a second end and configured to alter an effective thermal length of the wall member, wherein a first end of the wall member is communicatively coupled to a high temperature region and the second end of the wall member is communicatively coupled to a cryogen disposed within a cryogen vessel of the cryostat; and
a processing subsystem in operative association with the acquisition subsystem and configured to process the acquired image data.
